(19) United States
(12) Patent Application Publication
(10) Pub. No.: US 2023/0411932 A1
(43) Pub. Date: Dec. 21, 2023

(54) TUNABLE LASER ARRAY

(71) Applicant: Facebook Technologies, LLC, Menlo Park, CA (US)

(72) Inventors: Petr Markov, Seattle, WA (US); Alfredo Bismuto, Bellevue, WA (US); David Miller, Seattle, WA (US); Guohua Wei, Redmond, WA (US)

(21) Appl. No.: 17/842,471

(22) Filed: Jun. 16, 2022

(51) Int. Cl. H01S 5/40; G02B 27/01

(52) U.S. Cl. CPC H01S 5/4012; H01S 5/4087; G02B 27/017; G02B 2027/0178

(57) ABSTRACT

The disclosed tunable laser array may include multiple lasers including at least first and second lasers having center emission wavelengths that are separated by at least a specified minimum wavelength. The tunable laser array may also include at least one coupler/splitter. In the tunable laser array, emitted light from the first laser at a first wavelength and emitted light from the second laser at a second, different wavelength may be combined and then split at the coupler/splitter. Moreover, the lasers may have at least a minimum amount of thermal resistance. Various other systems, apparatuses, and methods of manufacturing are also disclosed.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 illustrates an embodiment of a tunable laser array having multiple laser light sources.

FIG. 2 illustrates an alternative embodiment of a tunable laser array having multiple laser light sources.

FIG. 3 illustrates an embodiment of a chart showing different laser light bandwidths used to achieve different axial resolutions.

FIG. 4 illustrates an embodiment of a chart showing electrical power levels used to achieve different laser light wavelengths.

FIG. 5 illustrates an embodiment in which a tunable laser array is embedded in a photonic integrated circuit (PIC).

FIG. 6 illustrates an embodiment in which a tunable laser array is embedded in a PIC, and the PIC is implemented in a wearable electronic device.

FIG. 7 illustrates a diagram in which input power is regulated to control output wavelengths of the laser light sources in a tunable laser array.

FIG. 8 is a flow diagram of an exemplary method for manufacturing a wearable electronic device that includes a tunable laser array.

FIG. 9 is an illustration of exemplary augmented-reality glasses that may be used in connection with embodiments of this disclosure.

FIG. 10 is an illustration of an exemplary virtual-reality headset that may be used in connection with embodiments of this disclosure.

FIG. 11 is an illustration of an exemplary system that incorporates an eye-tracking subsystem capable of tracking a user's eye(s).

FIG. 12 is a more detailed illustration of various aspects of the eye-tracking subsystem illustrated in FIG. 11.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

This present disclosure is generally directed to a tunable laser array that may be used in photonic integrated circuits (PICS) and, at least in some cases, may be used in eye-tracking applications. Other laser array systems have used a single, broadly tunable laser source to perform low coherence interferometry (LCI) and optical coherence tomography (OCT). To perform OCT high-resolution imaging, for example, these laser array systems have implemented laser sources that are quickly tunable (e.g., at frequencies between 80-250 kHz) and provide very precise levels of axial resolution (e.g., 5-15 um). Controlled and precise levels of continuous wavelength tuning are needed to achieve these minute levels of resolution. Laser sources that can provide this level of axial resolution and this high degree of tunability may include micro-electro-mechanical systems (MEMS) vertical-cavity surface-emitting lasers (VCSELs) (MEMS-VCSELs), external cavity tunable lasers, and Vernier effect tunable lasers.

These types of laser sources, however, are either too large to fit into wearable electronic devices, or are too difficult to continuously tune and control. For example, MEMS-VCSEL lasers require voltages too high for wearable devices, while external cavity tunable lasers have a form factor that is too large for wearable devices. Vernier effect tunable lasers are inherently difficult to control and tune continuously, and are much less efficient than single mode lasers. The embodiments described herein, in contrast, aim to implement a sparse OCT architecture with discrete outputs rather than continuous scanning, and may take advantage of typically unwanted wavelength tuning effects that occur due to the heating of the laser junctions in the laser sources. These embodiments may allow the sparse OCT architecture to be integrated into photonic integrated circuits and wearable devices.

Indeed, the embodiments described herein may implement an array of source lasers, each having a center emission wavelength that is slightly offset from the other (e.g., a 2.5 nm offset between center wavelengths). The emissions from each offset laser source may then be combined and split by coupler/splitters (e.g., 2×2 3 dB coupler/splitters) to create multiple (substantially lossless) laser outputs. These laser outputs may provide a level of axial resolution that may be too low for LCI or OCT high-resolution imaging, but may be large enough to function in an eye-tracking system in a wearable device. The laser sources described herein may be tunable by intentionally changing the temperature of the laser source at the laser junction. These laser sources may be designed (contrary to other systems that attempt to maintain a constant temperature) to have thermal qualities that allow for quick changes in temperature.

In some cases, for example, the laser sources described herein may be tuned by varying the amount of applied power or electrical current. As current flows to the laser sources, the laser junctions heat up, and the wavelengths of the output laser emissions change. Contrary to other systems that attempt to maintain a precise temperature to emit a specific wavelength, the embodiments herein may provide laser sources with thermal properties that allow for quick changes in temperature (e.g., low diffusivity or a maximum level of thermal resistance). These quick changes in temperature then provide corresponding changes in emitted wavelength. As mentioned above, this method of tuning may be too slow for many types of OCT applications including high-resolution imaging. However, the tuning speed provided by the tunable array of laser sources described herein may provide sufficient LCI resolution to perform eye tracking (e.g., 50 um), and may fit within a PIC on a wearable device.

Features from any of the embodiments described herein may be used in combination with one another in accordance with the general principles described herein. These and other embodiments, features, and advantages will be more fully understood upon reading the following detailed description in conjunction with the accompanying drawings and claims.

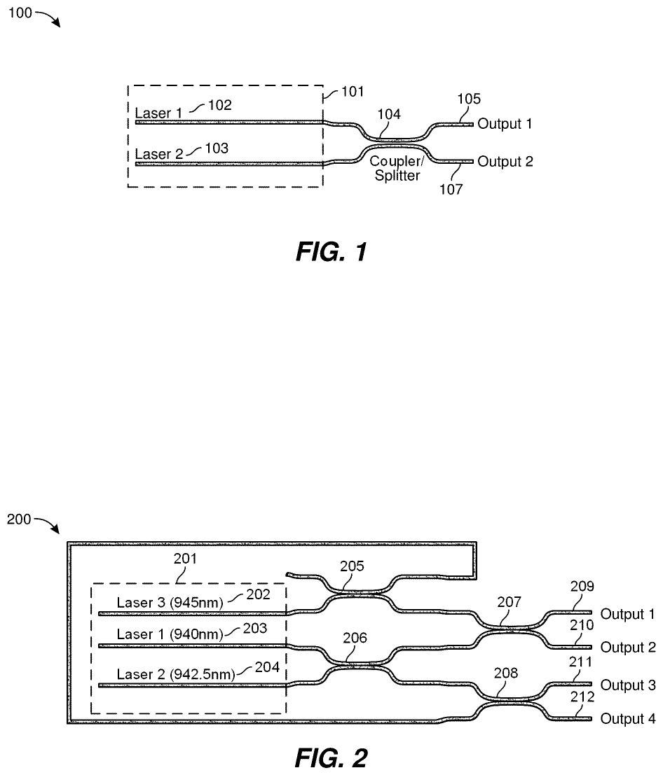

The following will provide, with reference to FIGS. 1-13, detailed descriptions of a tunable laser array, including the array's potential use in eye-tracking and augmented or virtual reality devices. The tunable laser array described herein may include substantially any number of lasers or laser sources. Thus, while the embodiments described herein include two, three, or four lasers, it will be understood that substantially any number of lasers and/or coupler/splitters may be used in the tunable laser array.

FIG. 1, for example, illustrates an embodiment 100 in which a tunable laser array 101 includes two laser sources 102 and 103. In this embodiment, laser 1 (102) may be directed at a first input of coupler/splitter 104, and laser 2 (103) may be directed at the second input of coupler/splitter 104. As the term is used herein, a “coupler/splitter” may refer to optical, mechanical, or other components or devices that are configured to simultaneously couple and split beams of laser light. In FIG. 1, the first coupler/splitter 104 may receive laser light from laser 1 (102) and laser 2 (103) and combine/split that light into two mixed beams. These output beams may then be directed at a user's eye to perform eye tracking, may be directed at a waveguide to help facilitate a waveguide display (e.g., on a photonic integrated circuit), or may be directed at another target.

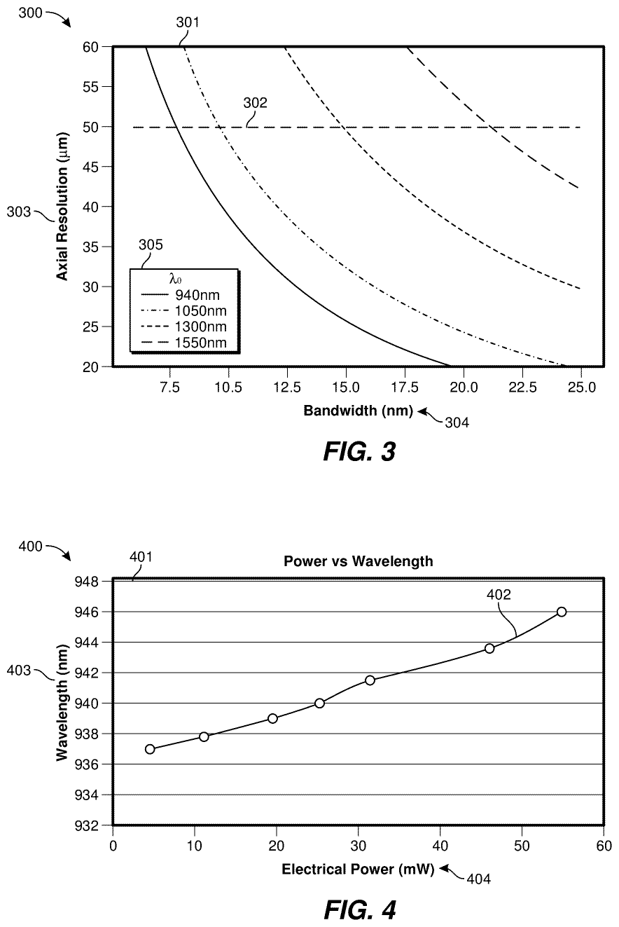

In embodiment 100, the laser beams of the tunable laser array 101 may be emitted at different, offset wavelengths. In order to provide certain functions, a specified minimum wavelength differential may be needed. For instance, to perform eye tracking, a system or device may require a minimum axial resolution of 50 um. To achieve an axial resolution of at a 940 nm wavelength, a minimum of 7 nm of continuous wavelength tuning may be stipulated (this will be described further below with regard to FIG. 3). To achieve 7 nm of tuning bandwidth, the lasers 1 & 2 of tunable laser array 101 may be configured to operate at wavelengths that are at least 7 nm apart. That is, the center emission wavelength of each laser 1 & 2 may have tuning ranges that add up to at least 7 nm.

For instance, if each laser in FIG. 1 is capable of tuning by 4 nm, the separation between the center emission wavelengths may be 3-4 nm. Accordingly, in embodiment 100, to provide a minimum axial resolution of 50 um at a 940 nm wavelength, laser 1 (102) may operate between 943-947 nm, and laser 2 (103) may operate between 940-944 nm (other spreads of 7 nm are also possible). Then, when the laser emissions from these lasers 1 & 2 are combined and split, the resulting laser outputs 105 and 107 may provide a tuning bandwidth of at least 7 nm, which, at least in this example, may be sufficient to perform eye tracking. Other applications may require different tuning bandwidths, which may be provided using different numbers of laser sources and using different center emission wavelengths at each laser source.

In contrast to other systems that attempt to closely maintain a constant temperature and thus a constant wavelength at each laser source, the embodiments herein may provide continuous wavelength tuning by intentionally varying the temperature of each laser source. The temperature may be varied, for example, by controlling the amount of electrical current flowing to each laser junction. Increased current flow to the laser junction may result in a hotter laser junction, while decreased current flow to the laser junction may result in a cooler laser junction. The embodiments herein may be configured to control current and control temperature changes quickly enough to provide a tuning speed of at least 10 kHz full sweep. While 10 kHz may be insufficient for high-resolution OCT imaging, this tuning speed may work very well for eye tracking and waveguide display applications. Moreover, the tunable laser arrays described herein may have a form factor and voltage requirements that are small enough to fit on a photonic integrated circuit (PIC), as will be described further below.

FIG. 2 illustrates an embodiment 200 in which a tunable laser array 201 includes three lasers: laser 3 (202), laser 1 (203), and laser 2 (204). In this embodiment, the three lasers 1-3, when combined and split as shown, may provide a continuously tunable wavelength of 7.5 nm. In this embodiment, the laser light from lasers 1 and 2 may be combined at coupler/splitter 206, and may then be combined again at coupler/splitter 208 with laser light from laser 3 that has traveled through coupler/splitter 205. The split light from coupler/splitter 206 may also be combined with light from laser 3 at coupler/splitter 207. The resulting sparse laser outputs 209-212 may be directed to a user's eyes, to a waveguide, or to another target or location.

As noted above, and as shown in FIG. 3, for some applications, a minimum axial resolution may be required. In embodiment 300 of FIG. 3, a chart 301 illustrates different axial resolutions along the y-axis (303), and the tuning bandwidth needed to achieve those axial resolutions. This tuning bandwidth is shown along the x-axis (304). The bandwidth needed to achieve a given axial resolution may change depending on which wavelength is being used. Accordingly, as shown in key 305, the different types of lines shown in the key and in the chart 301 may represent different axial resolutions at different bandwidths. Dashed line 302, for example, indicates a 50 um minimum resolution needed to perform eye tracking. Thus, at a wavelength of 940 nm, approximately 7.5 nm of tuning bandwidth is needed to provide 50 um of axial resolution. At 1050 nm, approximately 10 nm of bandwidth is needed to provide 50 um, and so on. In this manner, based on which center emission wavelength will be used, the systems herein may implement different numbers of lasers or may implement smaller or greater differences in center emission wavelengths to provide the specified minimum bandwidth that will lead to the desired axial resolution (e.g., 50 um in the case of eye tracking).

In order to tune the tunable laser array 201 of FIG. 2, the embodiments described herein may intentionally vary the temperature of the laser junction in the tunable laser array. The embodiments described herein may implement lasers that are less thermally diffusive or have a larger thermal resistance than other lasers. Indeed, while VCSEL and other lasers attempt to maintain a constant temperature to hold a laser beam at a constant output wavelength, the embodiments described herein may implement lasers whose junctions are made of materials that are more capable of quickly gaining heat (i.e., materials that are highly insulating such as oxides/nitrides including silicon dioxide (SiO₂), silicon nitride (SiN), etc.). Implementing materials with a low “diffusivity” or ability to quickly gain heat allows the lasers herein to be continuously tuned (e.g., at 10 kHz) by carefully changing the temperature of the laser junction. Changes to the temperature of the laser junction may be implemented by varying the amount of electrical current applied to the laser. In other cases, it should be noted, the lasers may be tuned using carrier injection tuning techniques, or using electro-optical tuning techniques.

In cases where the tunable laser array 201 is tuned by altering electrical current in amps (or by altering power in watts), the change in wavelength may occur in a largely linear manner. For example, as shown in chart 401 of FIG. 4, as more electrical power 404 is applied, the wavelength 403 may increase. Thus, for instance in this embodiment 400, and with reference to plotted data 402, at 10 mW, the wavelength of the tunable laser array 201 may be approximately 938 nm. At 20 mW, the wavelength of the tunable laser array 201 may be approximately 939 nm, and at 50 mW, the wavelength of the tunable laser array may be approximately 944 nm. Thus, by changing the input power or input current to the tunable laser array, the output wavelength of the lasers may be continuously tuned. Each laser in the laser array may be separately and individually tunable. Thus, in some cases, more current or power may be applied to one laser of the array, while less current or power is applied to another laser. The wavelengths of each of the lasers may be continuously tuned to provide a specific bandwidth for a desired axial resolution. As such, the embodiments described herein may be continuously tuned to provide, for instance, >7 nm of bandwidth which, at 940 nm wavelength, leads to a 50 um axial resolution. This level of resolution is sufficient for performing eye tracking, waveguide display implementations, and other applications.

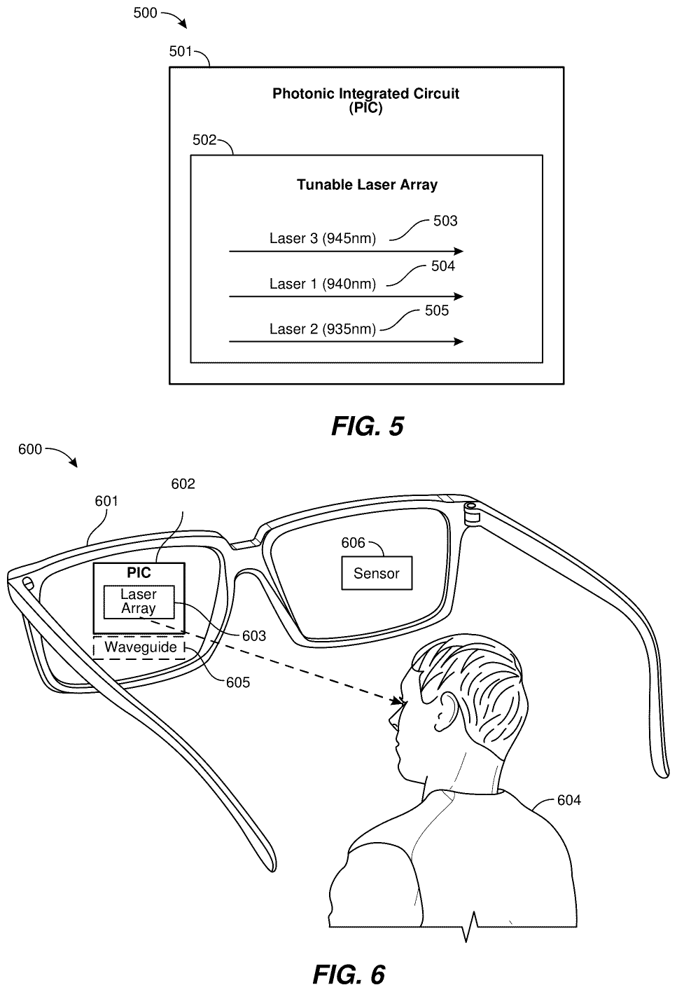

Indeed, as shown in embodiment 500 of FIG. 5, a tunable laser array 502 may be embedded on or otherwise provided on a photonic integrated circuit 501. The photonic integrated circuit may include other components, in addition to the tunable laser array 502, that are not shown here. The tunable laser array 502 may include multiple lasers configured in an array that is arranged either vertically or horizontally, including laser 3 (503) at 1055 nm, laser 1 (504) at 1050 nm, and laser 2 (505) at 1045 nm. In this example, the tunable laser array 502 may provide 10 nm of tunable bandwidth (i.e., the total offset of the three lasers' wavelengths). As can be seen on chart 301 of FIG. 3, an axial resolution of 50 um may be provided at 1050 nm with a bandwidth of approximately 10 nm. Accordingly, the spread between the three lasers 503-505 in this example may be 10 nm at 1050 nm. In other embodiments, such as scenarios that use larger wavelengths, a higher bandwidth may be needed to reach a minimum specified level of axial resolution. The tunable laser array 502 may receive power from a controller that is configured to individually supply power to and, thus, separately tune each laser.

In some cases, as shown in embodiment 600 of FIG. 6, the tunable laser array 603 may be directed at a specified target. For instance, the tunable laser array 603 may be directed at a user's eyes. Thus, the lasers of the tunable laser array 603 may be directed at user 604's eyes as the user dons the augmented reality glasses 601. The tunable laser array 603 may be disposed on a PIC 602 that is embedded in the augmented reality glasses 601. The augmented reality glasses 601 may also include a light sensor 606 configured to detect laser light reflected off of user 604's eyes. Thus, the tunable laser array 603 may direct its split laser outputs at user 604's eyes, and light sensor 606 may detect laser light reflections off of the user's eyes. These reflections may then be analyzed by a processor or controller to determine the user's eye movements. These eye movements may include horizontal, vertical, or diagonal movements, and may also determine the speed of those movements. In some cases, in order to provide these types of determinations, the laser light sources may need to operate at approximately 10 kHz. In other embodiments, such as waveguide display embodiments that implement waveguide 605, the continuous tuning may occur at a frequency that is more or less than 10 kHz.

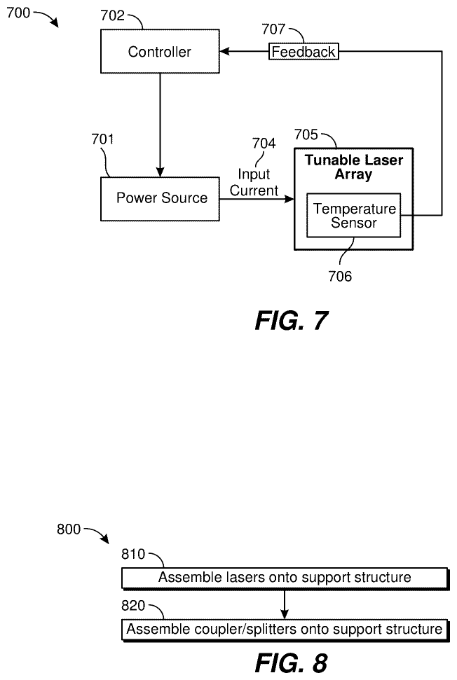

Additionally or alternatively, as shown in embodiment 700 of FIG. 7, a controller 702 may control the input current 704 (e.g., from power source 701) to the tunable laser array 705 based on a knowledge of the thermal characteristics of the lasers in the tunable laser array. Thus, for instance, if the lasers are made of a material with at least a minimum level of thermal resistance, the controller 702 will be able to vary the current quickly enough to tune the lasers at a minimum frequency (e.g., 10 kHz). Thus, the minimum level of thermal resistance may ensure that each laser has the ability to quickly heat up. The controller 702 may be aware of this minimum level of thermal resistance, and may thus know how quickly each separate laser may react to changes in input current (and thus changes in heat).

In some cases, lasers may have more than the minimum level of thermal resistance, and may thus heat even more quickly. In cases where the lasers do not meet the minimum level of thermal resistance for a given application (e.g., eye-tracking) (i.e., the lasers will not be able to heat quickly enough for that application), the controller may indicate to an operator that the desired application may not work (or may not work sufficiently well) for that application. Thus, to provide a minimum axial resolution and a minimum bandwidth, a corresponding minimum thermal resistance may be needed to ensure that the lasers can change temperature fast enough to be tuned at at least the frequency prescribed for that application (e.g., 10 kHz for eye tracking).

In some cases, the laser junctions may be shorter or longer. Shorter laser junctions may be more compact and may, thus, be better at gaining heat. Longer laser junctions, on the other hand, may include more material and may thus take longer to gain heat. Accordingly, the controller 702 may take these additional characteristics into consideration when determining how much power to send to each laser in the tunable laser array 705.

In some cases, the tunable laser array 705 of FIG. 7 may include a temperature sensor 706 (or potentially multiple temperature sensors). The temperature sensor(s) 706 may detect the current temperature of each laser of the laser array and may indicate that temperature to the controller 702 via feedback 707. The controller 702 may then regulate the amount of input current 704 or power that is being sent to each laser. This regulating process may send more power to heat the laser junction or may send less power, allowing the laser junction to cool slightly. The temperature sensors may detect the changes in temperature and send those changes back to the controller in feedback 707. In this manner, the controller 702 may implement a power regulator (or may directly modulate the power source 701) to control the flow of power or current to each laser junction in the tunable laser array 705. The flow of power may be changed very rapidly and, because the lasers of the tunable laser array 705 may be made of materials that quickly gain heat, the lasers may quickly change temperature and thus change wavelength along with the rapid changes in input power. In some cases, the center emission wavelength of at least one of the lasers in the tunable laser array 705 is tuned at a minimum of 1 nanometer/microsecond.

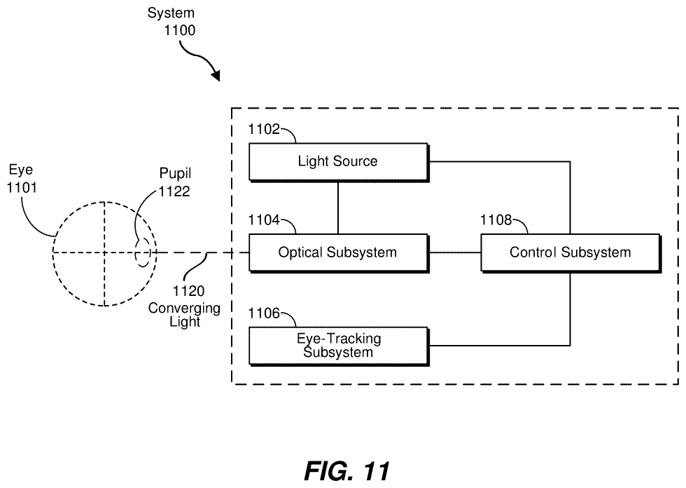

In some embodiments, a wearable mobile electronic device may be provided. The mobile electronic device may be an augmented reality device (e.g., 1000 of FIG. 10), a virtual reality device (e.g., system 1100 of FIG. 11), a smartphone, a smartwatch, or other similar device. The wearable mobile electronic devices described herein may include a support structure and multiple lasers disposed on the support structure that have offset center emission wavelengths. The combined offset in these different lasers may provide a total tuning bandwidth that may be provided by a tunable laser array. The wearable device may also include multiple coupler/splitters disposed on the support structure. Emitted light from one laser at a given wavelength and emitted light from another laser at a different wavelength may be combined and then split at a first coupler/splitter. That light may then ultimately be split into multiple sparse laser outputs at the second coupler/splitter. In some cases, the multiple sparse laser outputs may be coupled to other devices or target designations via different types of couplings including grating-couplings, fiber-couplings, or edge-couplings. Other types of couplings may also be used in different applications. Within this system, the various lasers of the tunable laser array may include at least a minimum level of thermal resistance that allows the lasers to heat quickly enough to provide sufficient bandwidth (and thus axial resolution) to carry out a given application.

FIG. 8 is a flow diagram of an exemplary method of manufacturing 800 for producing a wearable electronic device that includes a tunable laser array. The steps shown in FIG. 8 may be performed or controlled by any suitable computer-executable code and/or computing system, including embedded systems.

As illustrated in FIG. 8, at step 810, one or more of the systems described herein may assemble multiple lasers onto a support structure (e.g., a PIC). The lasers, including at least first and second lasers, may have center emission wavelengths that are separated by a specified minimum wavelength (e.g., 7 nm). Various industrial machines or components may be implemented to access and assemble the lasers onto the support structure (e.g., onto a tunable laser array). As described above, the lasers may be narrow band tunable lasers that may be losslessly combined using 2×2 3 dB coupler/splitters. Indeed, step 820 includes assembling multiple coupler/splitters onto the support structure (e.g., onto the tunable laser array).

In some cases, this manufactured system may further include a power source, a controller, and a power regulator. The controller may implement the power regulator to control how much power is sent to the tunable laser array. The tunable laser array may be manufactured using lasers that have at least a minimum level of thermal resistance or a minimum level of diffusivity. This minimum level of thermal resistance may ensure that heat can flow to or away from the lasers in a quick enough manner to allow tuning using the input power. Thus, in contrast to other systems that attempt to maintain a constant temperature and a constant wavelength, the embodiments herein may be configured to intentionally change the temperature of the laser sources and thus tune the output emissions of the offset lasers in the laser array. In this manner, with a plurality of lasers whose center emission lasers are offset from each other, the systems herein may continuously tune the laser array to provide a bandwidth sufficient to perform different tasks including performing eye tracking in a wearable electronic device.

### EXAMPLE EMBODIMENTS

Example 1: A tunable laser array may include a plurality of lasers including at least first and second lasers having center emission wavelengths that are separated by at least a specified minimum wavelength and at least one coupler/splitter, wherein emitted light from the first laser at a first wavelength and emitted light from the second laser at a second, different wavelength are combined and then split at the coupler/splitter, and wherein the plurality of lasers have at least a minimum level of thermal resistance.

Example 2: The tunable laser array of Example 1, wherein the multiple laser outputs are directed at a specified target.

Example 3: The tunable laser array of Example 1 or Example 2, wherein the multiple laser outputs are coupled to a waveguide to provide a display.

Example 4: The tunable laser array of any of Examples 1-3, wherein the specified target of the multiple laser outputs comprises one or more eyes of a user to perform eye tracking.

Example 5: The tunable laser array of any of Examples 1-4, further comprising a sensor configured to detect light reflecting from one or more of the user's eyes to perform the eye tracking.

Example 6: The tunable laser array of any of Examples 1-5, wherein the amount of separation in the center emission wavelengths of the plurality of lasers comprises a bandwidth that provides a specified axial resolution.

Example 7: The tunable laser array of any of Examples 1-6, wherein the tunable laser array is disposed within a photonic integrated circuit (PIC)

Example 8: The tunable laser array of any of Examples 1-7, wherein the PIC is implemented in a pair of artificial reality glasses.

Example 9: The tunable laser array of any of Examples 1-8, further including a third laser having a center emission wavelength that is separated from that of the first and second lasers by at least an additional specified minimum wavelength, a third coupler/splitter, and a fourth coupler/splitter, wherein emitted light from the first laser at the first wavelength and emitted light from the third laser at a third, different wavelength are combined and then split at the third coupler/splitter, and wherein split light from a second coupler/splitter is combined at the fourth coupler/splitter and is split into multiple laser outputs at the fourth coupler/splitter.

Example 10: The tunable laser array of any of Examples 1-9, wherein the amount of separation in the center emission wavelengths of the plurality of lasers comprises a bandwidth that provides a specified axial resolution.

Example 11: The tunable laser array of any of Examples 1-10, wherein the plurality of lasers is tuned by regulating an amount of electrical current flowing to the plurality of lasers.

Example 12: The tunable laser array of any of Examples 1-11, wherein an operating temperature of each of the plurality of lasers is regulated by the amount of electrical current flowing to the plurality of lasers, and wherein the operating temperature of the plurality of lasers governs the center emission wavelength of each laser.

Example 13: The tunable laser array of any of Examples 1-12, wherein the center emission wavelength of at least one of the plurality of lasers is tuned at at least 1 nanometer/microsecond.

Example 14: A wearable mobile electronic device may include a support structure, a plurality of lasers disposed on the support structure including at least first and second lasers having center emission wavelengths that are separated by at least a specified minimum wavelength, and at least one coupler/splitter disposed on the support structure, wherein emitted light from the first laser at a first wavelength and emitted light from the second laser at a second, different wavelength are combined and then split at the first coupler/splitter, and wherein the plurality of lasers have at least a minimum level of thermal resistance.

Example 15: The wearable mobile electronic device of Example 14, further including a controller that is configured to regulate an amount of electrical current flowing to each laser to modulate an operating temperature of the plurality of lasers.

Example 16: The wearable mobile electronic device of Example 14 or Example 15, further comprising a temperature sensor configured to determine an operating temperature of each of the plurality of lasers.

Example 17: The wearable mobile electronic device of any of Examples 14-16, wherein the controller increases or decreases the amount of electrical current flowing to the plurality of lasers to correspondingly increase or decrease the operating temperature of the plurality of lasers and thereby tune the plurality of lasers.

Example 18: The wearable mobile electronic device of any of Examples 14-17, wherein the multiple laser outputs resulting from the coupler/splitter comprise sparse beams.

Example 19: The wearable mobile electronic device of any of Examples 14-18, wherein the multiple laser outputs resulting from the coupler/splitter are at least one of grating-coupled, fiber-coupled, or edge-coupled.

Example 20: A method of manufacturing may include assembling a plurality of lasers onto a support structure, the plurality of lasers including at least first and second lasers having center emission wavelengths that are separated by at least a specified minimum wavelength, and assembling at least one coupler/splitter onto the support structure, wherein emitted light from the first laser at a first wavelength and emitted light from the second laser at a second, different wavelength are combined and then split at the coupler/splitter, and wherein the plurality of lasers have at least a minimum level of thermal resistance.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

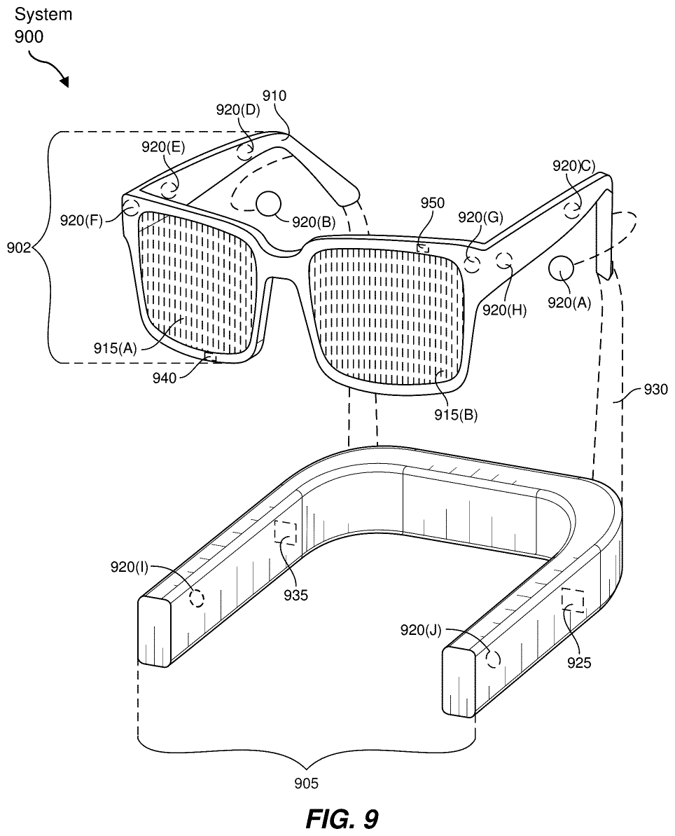

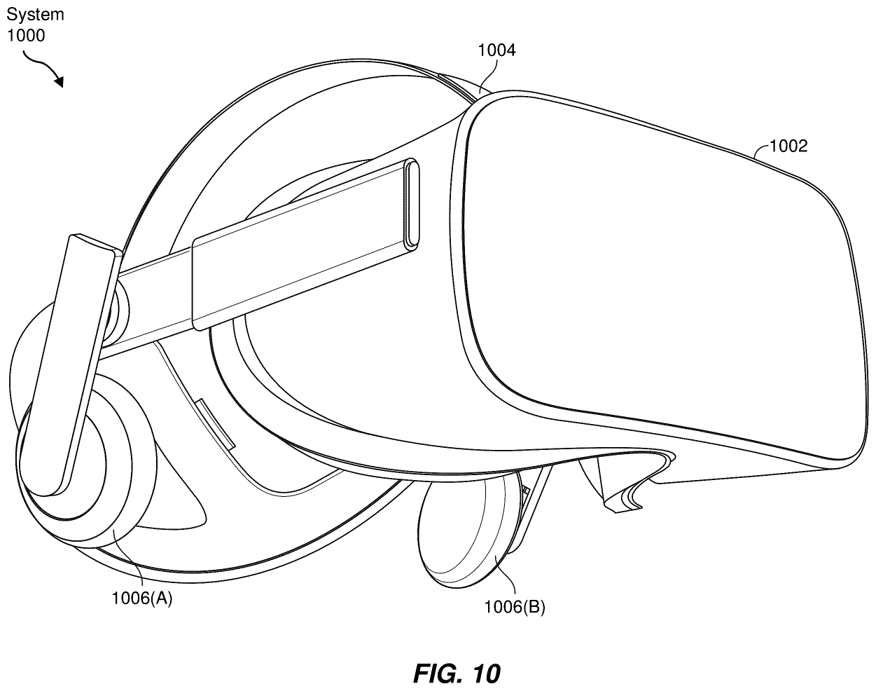

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 900 in FIG. 9) or that visually immerses a user in an artificial reality (such as, e.g., virtual-reality system 1000 in FIG. 10). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 9, augmented-reality system 900 may include an eyewear device 902 with a frame 910 configured to hold a left display device 915(A) and a right display device 915(B) in front of a user's eyes. Display devices 915(A) and 915(B) may act together or independently to present an image or series of images to a user. While augmented-reality system 900 includes two displays, embodiments of this disclosure may be implemented in augmented-reality systems with a single NED or more than two NEDs.

In some embodiments, augmented-reality system 900 may include one or more sensors, such as sensor 940. Sensor 940 may generate measurement signals in response to motion of augmented-reality system 900 and may be located on substantially any portion of frame 910. Sensor 940 may represent one or more of a variety of different sensing mechanisms, such as a position sensor, an inertial measurement unit (IMU), a depth camera assembly, a structured light emitter and/or detector, or any combination thereof. In some embodiments, augmented-reality system 900 may or may not include sensor 940 or may include more than one sensor. In embodiments in which sensor 940 includes an IMU, the IMU may generate calibration data based on measurement signals from sensor 940. Examples of sensor 940 may include, without limitation, accelerometers, gyroscopes, magnetometers, other suitable types of sensors that detect motion, sensors used for error correction of the IMU, or some combination thereof.

In some examples, augmented-reality system 900 may also include a microphone array with a plurality of acoustic transducers 920(A)-920(J), referred to collectively as acoustic transducers 920. Acoustic transducers 920 may represent transducers that detect air pressure variations induced by sound waves. Each acoustic transducer 920 may be configured to detect sound and convert the detected sound into an electronic format (e.g., an analog or digital format). The microphone array in FIG. 9 may include, for example, ten acoustic transducers: 920(A) and 920(B), which may be designed to be placed inside a corresponding ear of the user, acoustic transducers 920(C), 920(D), 920(E), 920(F), 920(G), and 920(H), which may be positioned at various locations on frame 910, and/or acoustic transducers 920(1) and 920(J), which may be positioned on a corresponding neckband 905.

In some embodiments, one or more of acoustic transducers 920(A)-(J) may be used as output transducers (e.g., speakers). For example, acoustic transducers 920(A) and/or 920(B) may be earbuds or any other suitable type of headphone or speaker.

The configuration of acoustic transducers 920 of the microphone array may vary. While augmented-reality system 900 is shown in FIG. 9 as having ten acoustic transducers 920, the number of acoustic transducers 920 may be greater or less than ten. In some embodiments, using higher numbers of acoustic transducers 920 may increase the amount of audio information collected and/or the sensitivity and accuracy of the audio information. In contrast, using a lower number of acoustic transducers 920 may decrease the computing power required by an associated controller 950 to process the collected audio information. In addition, the position of each acoustic transducer 920 of the microphone array may vary. For example, the position of an acoustic transducer 920 may include a defined position on the user, a defined coordinate on frame 910, an orientation associated with each acoustic transducer 920, or some combination thereof.

Acoustic transducers 920(A) and 920(B) may be positioned on different parts of the user's ear, such as behind the pinna, behind the tragus, and/or within the auricle or fossa. Or, there may be additional acoustic transducers 920 on or surrounding the ear in addition to acoustic transducers 920 inside the ear canal. Having an acoustic transducer 920 positioned next to an ear canal of a user may enable the microphone array to collect information on how sounds arrive at the ear canal. By positioning at least two of acoustic transducers 920 on either side of a user's head (e.g., as binaural microphones), augmented-reality system 900 may simulate binaural hearing and capture a 3D stereo sound field around about a user's head. In some embodiments, acoustic transducers 920(A) and 920(B) may be connected to augmented-reality system 900 via a wired connection 930, and in other embodiments acoustic transducers 920(A) and 920(B) may be connected to augmented-reality system 900 via a wireless connection (e.g., a BLUETOOTH connection). In still other embodiments, acoustic transducers 920(A) and 920(B) may not be used at all in conjunction with augmented-reality system 900.

Acoustic transducers 920 on frame 910 may be positioned in a variety of different ways, including along the length of the temples, across the bridge, above or below display devices 915(A) and 915(B), or some combination thereof. Acoustic transducers 920 may also be oriented such that the microphone array is able to detect sounds in a wide range of directions surrounding the user wearing the augmented-reality system 900. In some embodiments, an optimization process may be performed during manufacturing of augmented-reality system 900 to determine relative positioning of each acoustic transducer 920 in the microphone array.

In some examples, augmented-reality system 900 may include or be connected to an external device (e.g., a paired device), such as neckband 905. Neckband 905 generally represents any type or form of paired device. Thus, the following discussion of neckband 905 may also apply to various other paired devices, such as charging cases, smart watches, smart phones, wrist bands, other wearable devices, hand-held controllers, tablet computers, laptop computers, other external compute devices, etc.

As shown, neckband 905 may be coupled to eyewear device 902 via one or more connectors. The connectors may be wired or wireless and may include electrical and/or non-electrical (e.g., structural) components. In some cases, eyewear device 902 and neckband 905 may operate independently without any wired or wireless connection between them. While FIG. 9 illustrates the components of eyewear device 902 and neckband 905 in example locations on eyewear device 902 and neckband 905, the components may be located elsewhere and/or distributed differently on eyewear device 902 and/or neckband 905. In some embodiments, the components of eyewear device 902 and neckband 905 may be located on one or more additional peripheral devices paired with eyewear device 902, neckband 905, or some combination thereof.

Pairing external devices, such as neckband 905, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 900 may be provided by a paired device or shared between a paired device and an eyewear device, thus reducing the weight, heat profile, and form factor of the eyewear device overall while still retaining desired functionality. For example, neckband 905 may allow components that would otherwise be included on an eyewear device to be included in neckband 905 since users may tolerate a heavier weight load on their shoulders than they would tolerate on their heads. Neckband 905 may also have a larger surface area over which to diffuse and disperse heat to the ambient environment. Thus, neckband 905 may allow for greater battery and computation capacity than might otherwise have been possible on a stand-alone eyewear device. Since weight carried in neckband 905 may be less invasive to a user than weight carried in eyewear device 902, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 905 may be communicatively coupled with eyewear device 902 and/or to other devices. These other devices may provide certain functions (e.g., tracking, localizing, depth mapping, processing, storage, etc.) to augmented-reality system 900. In the embodiment of FIG. 9, neckband 905 may include two acoustic transducers (e.g., 920(1) and 920(J)) that are part of the microphone array (or potentially form their own microphone subarray). Neckband 905 may also include a controller 925 and a power source 935.

Acoustic transducers 920(1) and 920(J) of neckband 905 may be configured to detect sound and convert the detected sound into an electronic format (analog or digital). In the embodiment of FIG. 9, acoustic transducers 920(1) and 920(J) may be positioned on neckband 905, thereby increasing the distance between the neckband acoustic transducers 920(1) and 920(J) and other acoustic transducers 920 positioned on eyewear device 902. In some cases, increasing the distance between acoustic transducers 920 of the microphone array may improve the accuracy of beamforming performed via the microphone array. For example, if a sound is detected by acoustic transducers 920(C) and 920(D) and the distance between acoustic transducers 920(C) and 920(D) is greater than, e.g., the distance between acoustic transducers 920(D) and 920(E), the determined source location of the detected sound may be more accurate than if the sound had been detected by acoustic transducers 920(D) and 920(E).

Controller 925 of neckband 905 may process information generated by the sensors on neckband 905 and/or augmented-reality system 900. For example, controller 925 may process information from the microphone array that describes sounds detected by the microphone array. For each detected sound, controller 925 may perform a direction-of-arrival (DOA) estimation to estimate a direction from which the detected sound arrived at the microphone array. As the microphone array detects sounds, controller 925 may populate an audio data set with the information. In embodiments in which augmented-reality system 900 includes an inertial measurement unit, controller 925 may compute all inertial and spatial calculations from the IMU located on eyewear device 902. A connector may convey information between augmented-reality system 900 and neckband 905 and between augmented-reality system 900 and controller 925. The information may be in the form of optical data, electrical data, wireless data, or any other transmittable data form. Moving the processing of information generated by augmented-reality system 900 to neckband 905 may reduce weight and heat in eyewear device 902, making it more comfortable to the user.

Power source 935 in neckband 905 may provide power to eyewear device 902 and/or to neckband 905. Power source 935 may include, without limitation, lithium ion batteries, lithium-polymer batteries, primary lithium batteries, alkaline batteries, or any other form of power storage. In some cases, power source 935 may be a wired power source. Including power source 935 on neckband 905 instead of on eyewear device 902 may help better distribute the weight and heat generated by power source 935.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1000 in FIG. 10, that mostly or completely covers a user's field of view. Virtual-reality system 1000 may include a front rigid body 1002 and a band 1004 shaped to fit around a user's head. Virtual-reality system 1000 may also include output audio transducers 1006(A) and 1006(B). Furthermore, while not shown in FIG. 10, front rigid body 1002 may include one or more electronic elements, including one or more electronic displays, one or more inertial measurement units (IMUS), one or more tracking emitters or detectors, and/or any other suitable device or system for creating an artificial-reality experience.

Artificial-reality systems may include a variety of types of visual feedback mechanisms. For example, display devices in augmented-reality system 900 and/or virtual-reality system 1000 may include one or more liquid crystal displays (LCDs), light emitting diode (LED) displays, microLED displays, organic LED (OLED) displays, digital light projector (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 900 and/or virtual-reality system 1000 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 900 and/or virtual-reality system 1000 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

In some embodiments, the systems described herein may also include an eye-tracking subsystem designed to identify and track various characteristics of a user's eye(s), such as the user's gaze direction. The phrase “eye tracking” may, in some examples, refer to a process by which the position, orientation, and/or motion of an eye is measured, detected, sensed, determined, and/or monitored. The disclosed systems may measure the position, orientation, and/or motion of an eye in a variety of different ways, including through the use of various optical-based eye-tracking techniques, ultrasound-based eye-tracking techniques, etc. An eye-tracking subsystem may be configured in a number of different ways and may include a variety of different eye-tracking hardware components or other computer-vision components. For example, an eye-tracking subsystem may include a variety of different optical sensors, such as two-dimensional (2D) or 3D cameras, time-of-flight depth sensors, single-beam or sweeping laser rangefinders, 3D LiDAR sensors, and/or any other suitable type or form of optical sensor. In this example, a processing subsystem may process data from one or more of these sensors to measure, detect, determine, and/or otherwise monitor the position, orientation, and/or motion of the user's eye(s).

FIG. 11 is an illustration of an exemplary system 1100 that incorporates an eye-tracking subsystem capable of tracking a user's eye(s). As depicted in FIG. 11, system 1100 may include a light source 1102, an optical subsystem 1104, an eye-tracking subsystem 1106, and/or a control subsystem 1108. In some examples, light source 1102 may generate light for an image (e.g., to be presented to an eye 1101 of the viewer). Light source 1102 may represent any of a variety of suitable devices. For example, light source 1102 can include a two-dimensional projector (e.g., a LCoS display), a scanning source (e.g., a scanning laser), or other device (e.g., an LCD, an LED display, an OLED display, an active-matrix OLED display (AMOLED), a transparent OLED display (TOLED), a waveguide, or some other display capable of generating light for presenting an image to the viewer). In some examples, the image may represent a virtual image, which may refer to an optical image formed from the apparent divergence of light rays from a point in space, as opposed to an image formed from the light ray's actual divergence.

In some embodiments, optical subsystem 1104 may receive the light generated by light source 1102 and generate, based on the received light, converging light 1120 that includes the image. In some examples, optical subsystem 1104 may include any number of lenses (e.g., Fresnel lenses, convex lenses, concave lenses), apertures, filters, mirrors, prisms, and/or other optical components, possibly in combination with actuators and/or other devices. In particular, the actuators and/or other devices may translate and/or rotate one or more of the optical components to alter one or more aspects of converging light 1120. Further, various mechanical couplings may serve to maintain the relative spacing and/or the orientation of the optical components in any suitable combination.

In one embodiment, eye-tracking subsystem 1106 may generate tracking information indicating a gaze angle of an eye 1101 of the viewer. In this embodiment, control subsystem 1108 may control aspects of optical subsystem 1104 (e.g., the angle of incidence of converging light 1120) based at least in part on this tracking information. Additionally, in some examples, control subsystem 1108 may store and utilize historical tracking information (e.g., a history of the tracking information over a given duration, such as the previous second or fraction thereof) to anticipate the gaze angle of eye 1101 (e.g., an angle between the visual axis and the anatomical axis of eye 1101). In some embodiments, eye-tracking subsystem 1106 may detect radiation emanating from some portion of eye 1101 (e.g., the cornea, the iris, the pupil, or the like) to determine the current gaze angle of eye 1101. In other examples, eye-tracking subsystem 1106 may employ a wavefront sensor to track the current location of the pupil.

Any number of techniques can be used to track eye 1101. Some techniques may involve illuminating eye 1101 with infrared light and measuring reflections with at least one optical sensor that is tuned to be sensitive to the infrared light. Information about how the infrared light is reflected from eye 1101 may be analyzed to determine the position(s), orientation(s), and/or motion(s) of one or more eye feature(s), such as the cornea, pupil, iris, and/or retinal blood vessels.

In some examples, the radiation captured by a sensor of eye-tracking subsystem 1106 may be digitized (i.e., converted to an electronic signal). Further, the sensor may transmit a digital representation of this electronic signal to one or more processors (for example, processors associated with a device including eye-tracking subsystem 1106). Eye-tracking subsystem 1106 may include any of a variety of sensors in a variety of different configurations. For example, eye-tracking subsystem 1106 may include an infrared detector that reacts to infrared radiation. The infrared detector may be a thermal detector, a photonic detector, and/or any other suitable type of detector. Thermal detectors may include detectors that react to thermal effects of the incident infrared radiation.

In some examples, one or more processors may process the digital representation generated by the sensor(s) of eye-tracking subsystem 1106 to track the movement of eye 1101. In another example, these processors may track the movements of eye 1101 by executing algorithms represented by computer-executable instructions stored on non-transitory memory. In some examples, on-chip logic (e.g., an application-specific integrated circuit or ASIC) may be used to perform at least portions of such algorithms. As noted, eye-tracking subsystem 1106 may be programmed to use an output of the sensor(s) to track movement of eye 1101. In some embodiments, eye-tracking subsystem 1106 may analyze the digital representation generated by the sensors to extract eye rotation information from changes in reflections. In one embodiment, eye-tracking subsystem 1106 may use corneal reflections or glints (also known as Purkinje images) and/or the center of the eye's pupil 1122 as features to track over time.

In some embodiments, eye-tracking subsystem 1106 may use the center of the eye's pupil 1122 and infrared or near-infrared, non-collimated light to create corneal reflections. In these embodiments, eye-tracking subsystem 1106 may use the vector between the center of the eye's pupil 1122 and the corneal reflections to compute the gaze direction of eye 1101. In some embodiments, the disclosed systems may perform a calibration procedure for an individual (using, e.g., supervised or unsupervised techniques) before tracking the user's eyes. For example, the calibration procedure may include directing users to look at one or more points displayed on a display while the eye-tracking system records the values that correspond to each gaze position associated with each point.

In some embodiments, eye-tracking subsystem 1106 may use two types of infrared and/or near-infrared (also known as active light) eye-tracking techniques: bright-pupil and dark-pupil eye tracking, which may be differentiated based on the location of an illumination source with respect to the optical elements used. If the illumination is coaxial with the optical path, then eye 1101 may act as a retroreflector as the light reflects off the retina, thereby creating a bright pupil effect similar to a red-eye effect in photography. If the illumination source is offset from the optical path, then the eye's pupil 1122 may appear dark because the retroreflection from the retina is directed away from the sensor. In some embodiments, bright-pupil tracking may create greater iris/pupil contrast, allowing more robust eye tracking with iris pigmentation, and may feature reduced interference (e.g., interference caused by eyelashes and other obscuring features). Bright-pupil tracking may also allow tracking in lighting conditions ranging from total darkness to a very bright environment.

In some embodiments, control subsystem 1108 may control light source 1102 and/or optical subsystem 1104 to reduce optical aberrations (e.g., chromatic aberrations and/or monochromatic aberrations) of the image that may be caused by or influenced by eye 1101. In some examples, as mentioned above, control subsystem 1108 may use the tracking information from eye-tracking subsystem 1106 to perform such control. For example, in controlling light source 1102, control subsystem 1108 may alter the light generated by light source 1102 (e.g., by way of image rendering) to modify (e.g., pre-distort) the image so that the aberration of the image caused by eye 1101 is reduced.

The disclosed systems may track both the position and relative size of the pupil (since, e.g., the pupil dilates and/or contracts). In some examples, the eye-tracking devices and components (e.g., sensors and/or sources) used for detecting and/or tracking the pupil may be different (or calibrated differently) for different types of eyes. For example, the frequency range of the sensors may be different (or separately calibrated) for eyes of different colors and/or different pupil types, sizes, and/or the like. As such, the various eye-tracking components (e.g., infrared sources and/or sensors) described herein may need to be calibrated for each individual user and/or eye.

The disclosed systems may track both eyes with and without ophthalmic correction, such as that provided by contact lenses worn by the user. In some embodiments, ophthalmic correction elements (e.g., adjustable lenses) may be directly incorporated into the artificial reality systems described herein. In some examples, the color of the user's eye may necessitate modification of a corresponding eye-tracking algorithm. For example, eye-tracking algorithms may need to be modified based at least in part on the differing color contrast between a brown eye and, for example, a blue eye.

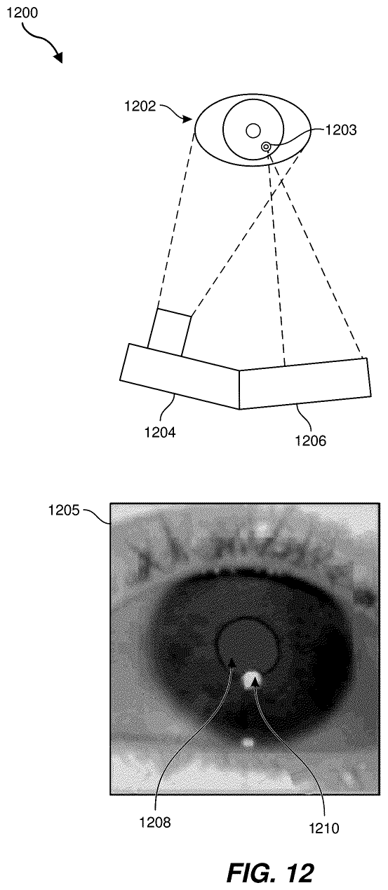

FIG. 12 is a more detailed illustration of various aspects of the eye-tracking subsystem illustrated in FIG. 11. As shown in this figure, an eye-tracking subsystem 1200 may include at least one source 1204 and at least one sensor 1206. Source 1204 generally represents any type or form of element capable of emitting radiation. In one example, source 1204 may generate visible, infrared, and/or near-infrared radiation. In some examples, source 1204 may radiate non-collimated infrared and/or near-infrared portions of the electromagnetic spectrum towards an eye 1202 of a user. Source 1204 may utilize a variety of sampling rates and speeds. For example, the disclosed systems may use sources with higher sampling rates in order to capture fixational eye movements of a user's eye 1202 and/or to correctly measure saccade dynamics of the user's eye 1202. As noted above, any type or form of eye-tracking technique may be used to track the user's eye 1202, including optical-based eye-tracking techniques, ultrasound-based eye-tracking techniques, etc.

Sensor 1206 generally represents any type or form of element capable of detecting radiation, such as radiation reflected off the user's eye 1202. Examples of sensor 1206 include, without limitation, a charge coupled device (CCD), a photodiode array, a complementary metal-oxide-semiconductor (CMOS) based sensor device, and/or the like. In one example, sensor 1206 may represent a sensor having predetermined parameters, including, but not limited to, a dynamic resolution range, linearity, and/or other characteristic selected and/or designed specifically for eye tracking.

As detailed above, eye-tracking subsystem 1200 may generate one or more glints. As detailed above, a glint 1203 may represent reflections of radiation (e.g., infrared radiation from an infrared source, such as source 1204) from the structure of the user's eye. In various embodiments, glint 1203 and/or the user's pupil may be tracked using an eye-tracking algorithm executed by a processor (either within or external to an artificial reality device). For example, an artificial reality device may include a processor and/or a memory device in order to perform eye tracking locally and/or a transceiver to send and receive the data necessary to perform eye tracking on an external device (e.g., a mobile phone, cloud server, or other computing device).

FIG. 12 shows an example image 1205 captured by an eye-tracking subsystem, such as eye-tracking subsystem 1200. In this example, image 1205 may include both the user's pupil 1208 and a glint 1210 near the same. In some examples, pupil 1208 and/or glint 1210 may be identified using an artificial-intelligence-based algorithm, such as a computer-vision-based algorithm. In one embodiment, image 1205 may represent a single frame in a series of frames that may be analyzed continuously in order to track the eye 1202 of the user. Further, pupil 1208 and/or glint 1210 may be tracked over a period of time to determine a user's gaze.

In one example, eye-tracking subsystem 1200 may be configured to identify and measure the inter-pupillary distance (IPD) of a user. In some embodiments, eye-tracking subsystem 1200 may measure and/or calculate the IPD of the user while the user is wearing the artificial reality system. In these embodiments, eye-tracking subsystem 1200 may detect the positions of a user's eyes and may use this information to calculate the user's IPD.

As noted, the eye-tracking systems or subsystems disclosed herein may track a user's eye position and/or eye movement in a variety of ways. In one example, one or more light sources and/or optical sensors may capture an image of the user's eyes. The eye-tracking subsystem may then use the captured information to determine the user's inter-pupillary distance, interocular distance, and/or a 3D position of each eye (e.g., for distortion adjustment purposes), including a magnitude of torsion and rotation (i.e., roll, pitch, and yaw) and/or gaze directions for each eye. In one example, infrared light may be emitted by the eye-tracking subsystem and reflected from each eye. The reflected light may be received or detected by an optical sensor and analyzed to extract eye rotation data from changes in the infrared light reflected by each eye.

The eye-tracking subsystem may use any of a variety of different methods to track the eyes of a user. For example, a light source (e.g., infrared light-emitting diodes) may emit a dot pattern onto each eye of the user. The eye-tracking subsystem may then detect (e.g., via an optical sensor coupled to the artificial reality system) and analyze a reflection of the dot pattern from each eye of the user to identify a location of each pupil of the user. Accordingly, the eye-tracking subsystem may track up to six degrees of freedom of each eye (i.e., 3D position, roll, pitch, and yaw) and at least a subset of the tracked quantities may be combined from two eyes of a user to estimate a gaze point (i.e., a 3D location or position in a virtual scene where the user is looking) and/or an IPD.

In some cases, the distance between a user's pupil and a display may change as the user's eye moves to look in different directions. The varying distance between a pupil and a display as viewing direction changes may be referred to as “pupil swim” and may contribute to distortion perceived by the user as a result of light focusing in different locations as the distance between the pupil and the display changes. Accordingly, measuring distortion at different eye positions and pupil distances relative to displays and generating distortion corrections for different positions and distances may allow mitigation of distortion caused by pupil swim by tracking the 3D position of a user's eyes and applying a distortion correction corresponding to the 3D position of each of the user's eyes at a given point in time. Thus, knowing the 3D position of each of a user's eyes may allow for the mitigation of distortion caused by changes in the distance between the pupil of the eye and the display by applying a distortion correction for each 3D eye position. Furthermore, as noted above, knowing the position of each of the user's eyes may also enable the eye-tracking subsystem to make automated adjustments for a user's IPD.

In some embodiments, a display subsystem may include a variety of additional subsystems that may work in conjunction with the eye-tracking subsystems described herein. For example, a display subsystem may include a varifocal subsystem, a scene-rendering module, and/or a vergence-processing module. The varifocal subsystem may cause left and right display elements to vary the focal distance of the display device. In one embodiment, the varifocal subsystem may physically change the distance between a display and the optics through which it is viewed by moving the display, the optics, or both. Additionally, moving or translating two lenses relative to each other may also be used to change the focal distance of the display. Thus, the varifocal subsystem may include actuators or motors that move displays and/or optics to change the distance between them. This varifocal subsystem may be separate from or integrated into the display subsystem. The varifocal subsystem may also be integrated into or separate from its actuation subsystem and/or the eye-tracking subsystems described herein.

In one example, the display subsystem may include a vergence-processing module configured to determine a vergence depth of a user's gaze based on a gaze point and/or an estimated intersection of the gaze lines determined by the eye-tracking subsystem. Vergence may refer to the simultaneous movement or rotation of both eyes in opposite directions to maintain single binocular vision, which may be naturally and automatically performed by the human eye. Thus, a location where a user's eyes are verged is where the user is looking and is also typically the location where the user's eyes are focused. For example, the vergence-processing module may triangulate gaze lines to estimate a distance or depth from the user associated with intersection of the gaze lines. The depth associated with intersection of the gaze lines may then be used as an approximation for the accommodation distance, which may identify a distance from the user where the user's eyes are directed. Thus, the vergence distance may allow for the determination of a location where the user's eyes should be focused and a depth from the user's eyes at which the eyes are focused, thereby providing information (such as an object or plane of focus) for rendering adjustments to the virtual scene.

The vergence-processing module may coordinate with the eye-tracking subsystems described herein to make adjustments to the display subsystem to account for a user's vergence depth. When the user is focused on something at a distance, the user's pupils may be slightly farther apart than when the user is focused on something close. The eye-tracking subsystem may obtain information about the user's vergence or focus depth and may adjust the display subsystem to be closer together when the user's eyes focus or verge on something close and to be farther apart when the user's eyes focus or verge on something at a distance.

The eye-tracking information generated by the above-described eye-tracking subsystems may also be used, for example, to modify various aspect of how different computer-generated images are presented. For example, a display subsystem may be configured to modify, based on information generated by an eye-tracking subsystem, at least one aspect of how the computer-generated images are presented. For instance, the computer-generated images may be modified based on the user's eye movement, such that if a user is looking up, the computer-generated images may be moved upward on the screen. Similarly, if the user is looking to the side or down, the computer-generated images may be moved to the side or downward on the screen. If the user's eyes are closed, the computer-generated images may be paused or removed from the display and resumed once the user's eyes are back open.

The above-described eye-tracking subsystems can be incorporated into one or more of the various artificial reality systems described herein in a variety of ways. For example, one or more of the various components of system 1100 and/or eye-tracking subsystem 1200 may be incorporated into augmented-reality system 900 in FIG. 9 and/or virtual-reality system 1000 in FIG. 10 to enable these systems to perform various eye-tracking tasks (including one or more of the eye-tracking operations described herein).

As detailed above, the computing devices and systems described and/or illustrated herein, including computing systems used to control manufacturing processes and/or, more specifically, the methods of manufacturing described herein, broadly represent any type or form of computing device or system capable of executing computer-readable instructions, such as those contained within the modules described herein. In their most basic configuration, these computing device(s) may each include at least one memory device and at least one physical processor.

In some examples, the term “memory device” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In some examples, the term “physical processor” generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. Additionally or alternatively, one or more of the modules recited herein may transform a processor, volatile memory, non-volatile memory, and/or any other portion of a physical computing device from one form to another by executing on the computing device, storing data on the computing device, and/or otherwise interacting with the computing device.

In some embodiments, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A tunable laser array comprising:
a plurality of lasers including at least first and second lasers having center emission wavelengths that are separated by at least a specified minimum wavelength; and
at least one coupler/splitter,
wherein emitted light from the first laser at a first wavelength and emitted light from the second laser at a second, different wavelength are combined and then split at the coupler/splitter, and
wherein the plurality of lasers have at least a minimum level of thermal resistance.

2. The tunable laser array of claim 1, wherein the multiple laser outputs are directed at a specified target.

3. The tunable laser array of claim 2, wherein the multiple laser outputs are coupled with a waveguide of a photonic integrated circuit.

4. The tunable laser array of claim 2, wherein the specified target of the multiple laser outputs comprises one or more eyes of a user to perform eye tracking.

5. The tunable laser array of claim 4, further comprising a sensor configured to detect light reflecting from one or more of the user's eyes to perform the eye tracking.

6. The tunable laser array of claim 1, wherein an amount of separation in the center emission wavelengths of the plurality of lasers comprises a bandwidth that provides a specified axial resolution.

7. The tunable laser array of claim 1, wherein the tunable laser array is disposed within a photonic integrated circuit (PIC).

8. The tunable laser array of claim 7, wherein the PIC is implemented in a pair of augmented reality glasses.

9. The tunable laser array of claim 1, further comprising:
a third laser having a center emission wavelength that is separated from that of the first and second lasers by at least an additional specified minimum wavelength;
a third coupler/splitter; and
a fourth coupler/splitter,
wherein emitted light from the first laser at the first wavelength and emitted light from the third laser at a third, different wavelength are combined and then split at the third coupler/splitter, and
wherein split light from a second coupler/splitter is combined at the fourth coupler/splitter and is split into multiple laser outputs at the fourth coupler/splitter.

10. The tunable laser array of claim 9, wherein an amount of separation in the center emission wavelengths of the plurality of lasers comprises a bandwidth that provides a specified axial resolution.

11. The tunable laser array of claim 1, wherein the plurality of lasers is tuned by regulating an amount of electrical current flowing to the plurality of lasers.

12. The tunable laser array of claim 11, wherein an operating temperature of each of the plurality of lasers is regulated by the amount of electrical current flowing to the plurality of lasers, and wherein the operating temperature of the plurality of lasers governs the center emission wavelength of each laser.

13. The tunable laser array of claim 11, wherein the center emission wavelength of at least one of the plurality of lasers is tuned at at least 1 nanometer/microsecond.

14. A wearable mobile electronic device comprising:
a support structure;
a plurality of lasers disposed on the support structure including at least first and second lasers having center emission wavelengths that are separated by at least a specified minimum wavelength; and
at least one coupler/splitter disposed on the support structure,
wherein emitted light from the first laser at a first wavelength and emitted light from the second laser at a second, different wavelength are combined and then split at the coupler/splitter, and
wherein the plurality of lasers have at least a minimum level of thermal resistance.

15. The wearable mobile electronic device of claim 14, further comprising a controller that is configured to regulate an amount of electrical current flowing to each laser to modulate an operating temperature of the plurality of lasers.

16. The wearable mobile electronic device of claim 15, further comprising a temperature sensor configured to determine an operating temperature of each of the plurality of lasers.

17. The wearable mobile electronic device of claim 16, wherein the controller increases or decreases the amount of electrical current flowing to the plurality of lasers to correspondingly increase or decrease the operating temperature of the plurality of lasers and thereby tune the plurality of lasers.

18. The wearable mobile electronic device of claim 14, wherein the multiple laser outputs resulting from the coupler/splitter comprise sparse beams.

19. The wearable mobile electronic device of claim 14, wherein the multiple laser outputs resulting from the coupler/splitter are at least one of grating-coupled, fiber-coupled, or edge-coupled.

20. A method of manufacturing comprising:
assembling a plurality of lasers onto a support structure, the plurality of lasers including at least first and second lasers having center emission wavelengths that are separated by at least a specified minimum wavelength; and
assembling at least one coupler/splitter onto the support structure,
wherein emitted light from the first laser at a first wavelength and emitted light from the second laser at a second, different wavelength are combined and then split at the coupler/splitter, and
wherein the plurality of lasers have at least a minimum level of thermal resistance.
